(19) United States
(12) Patent Application Publication
(10) Pub. No.: US 2004/0114415 A1
(43) Pub. Date: Jun. 17, 2004

(54) Structure of post-process one-time programmable read only memory cell

(76) Inventor: WenYing Wen, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/320,447

(22) Filed: Dec. 17, 2002

(51) Int. Cl. G11C 17/12

(52) U.S. Cl. 365/104

(57) ABSTRACT

The present invention generally relates to a structure of a post-process one-time programmable (OTP) read only memory cell (ROM cell). The OTP ROM cell has two oxide layers positioned on a semiconductor substrate and a plurality of semiconductor-implanted regions are implanted in the semiconductor substrate. Oxide layers are respectively to those semiconductor-implanted regions of the semiconductor substrate and having a window-type isolating channel region for each. Finally, a polysilicon layer is positioned on the thicker oxide layer as a gate electrode region of the OTP ROM cell. Hence, the polysilicon layer can be applied a voltage to penetrate the thinker oxide layer of the window-type isolating channel region to form a P-N junction between the semiconductor-implanted regions and the polysilicon layer and then the ROM cell is programmed.

### BACKGROUND OF THE INVENTION

1. Field of the Invention

The present invention generally relates to a structure of a read only memory cell (ROM cell), and more particularly relates to a structure of a post-process one-time programmable (OTP) read only memory cell (ROM cell).

2. Description of the Prior Art

In view of the programming process of the conventional read only memory product must be simultaneously performed in the manufacture process. When the manufacturer builds the product according to the order received from the customer, the actual amount of the product produced is usually larger than the order so as to avoid the short delivery of the product. However, it will cause excess product to storage in the depot after delivering and it will increase the manufacturing cost. Furthermore, the manufacturer could not immediately provide the goods of the programmed read only memory to customers because the read only memory product requires performing the programming process simultaneously in the manufacturing process.

Referring to FIG. 1A and FIG. 1B, a conventional ROM cell array is shown as a schematic representation of a structure and a cross-section view, in accordance with prior techniques. As shown in figures, a substrate 10′ is a P type semiconductor and the semiconductor substrate 10′ is ions-implanted to form a plurality N type semiconductor-implanted regions 12′ (as a bit line of the ROM cell) respectively to divide into a drain region and a source region. Following, an oxide layer 14′ and a polysilicon layer are sequentially formed on the semiconductor substrate 10′. The polysilicon layer (as word line of the ROM cell) is used as the gate electrode of the ROM cell. Wherein the programming region of the ROM cell is positioned between those N type semiconductor-implanted regions 12′, where are signed regions 18′. Consequently, it could be understood the certainty that the conventional read only memory must simultaneously perform the programming process in the manufacture process.

Obviously, the main spirit of the present invention is to provide a structure of a post-process OTP ROM cell, and then some disadvantages of well-known technology are overcome.

### SUMMARY OF THE INVENTION

The primary object of the invention is to provide a structure of a post-process one-time programmable (OTP) read only memory cell (ROM cell), wherein a sunken window-type isolating channel is formed by the oxide layer, which is positioned between the semiconductor-implanted regions and the polysilicon layer in the semiconductor substrate. After the manufacture process, the ROM cell can be programmed by applying a voltage thereon to penetrate the sunken window-type isolating channel.

Another object of the invention is to provide a structure of a post-process OTP ROM cell, wherein a sunken window-type isolating channel is formed by the oxide layer, which is positioned between the semiconductor-implanted regions and the polysilicon layer in the semiconductor substrate. Due to the cross-section width of the window-type isolating channel is smaller than or equal to a cross-section width of the semiconductor-implanted regions and is positioned aligned within the cross-section width of those semiconductor-implanted regions, the structure of the present invention can effectively enhance the stability of the programming process.

A further object of the invention is to provide a structure of a post-process OTP ROM cell. Without the require of simultaneously performing the programming process in the manufacture process, the manufacturers can instantaneously perform the programming process of the post-process OTP ROM cell of available goods after receiving the customer's order. This can enhance the maneuverability of the supply without the pressure from storing the large number of the stocks.

In order to achieve previous objects, the present invention provides a structure of a post-process OTP ROM cell. The structure of the present invention comprises a semiconductor substrate having a plurality of semiconductor-implanted regions therein respectively to divide into a drain region and a source region. The structure also comprises a first oxide layer on the semiconductor substrate. The first oxide layer has a plurality of sunken portions respectively to those semiconductor-implanted regions in the semiconductor substrate. The structure further comprises a second oxide layer on the first oxide layer and a polysilicon layer on the second oxide layer, wherein the polysilicon layer is used as the gate electrode of the ROM cell and is bar-positioned appropriately on the second oxide layer

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A is a schematic representation of the structure of a read only memory cell array, in accordance with prior techniques;

FIG. 1B is a schematic representation of the cross-section view of a read only memory cell array, in accordance with prior techniques;

FIG. 2 is a schematic representation of the structure of a read only memory cell array, in accordance with the present invention;

FIG. 3A is a schematic representation of the structure of a read only memory cell array, in accordance with one preferred embodiment of the present invention; and

FIG. 3B is a schematic representation of the circuit of a read only memory cell array, in accordance with one preferred embodiment of the present invention.

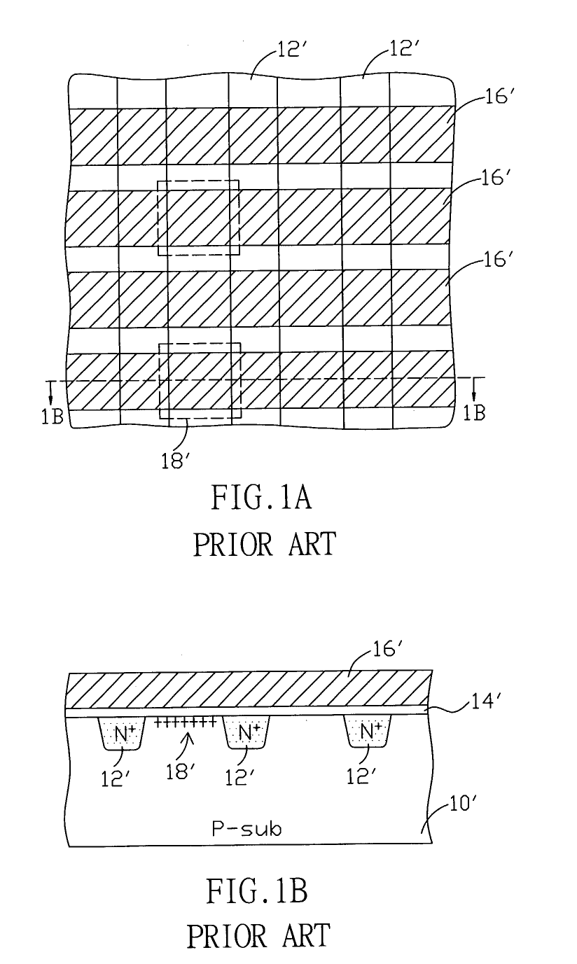

### DESCRIPTION OF THE PREFERRED EMBODIMENT

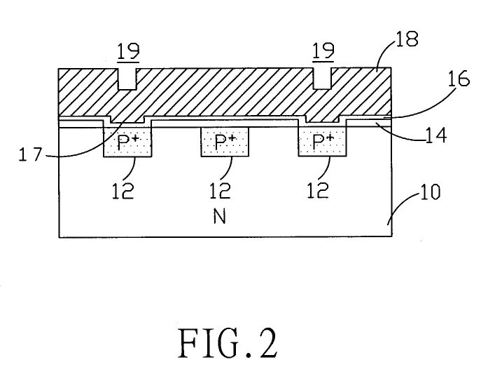

Referring to the FIG. 2, it is a structure of a read only memory cell (ROM cell), which can be one-time programmed post-process. The structure comprises a N type semiconductor substrate 10, wherein the substrate 10 has a plurality of P type semiconductor-implanted regions 12 therein respectively to divide into a drain region and a source region. A first oxide layer 14 is on the surface of the semiconductor substrate 10, wherein the first oxide layer 14 has a plurality of sunken region 15 respectively to those P type semiconductor-implanted regions 12 of the N type semiconductor substrate 10. A second oxide layer 16 is conformably on the first oxide layer 14. Besides, a polysilicon layer 18 is bar-positioned appropriately on the second oxide layer 16 and used as the gate electrode of the ROM cell. Wherein in the structure, the overlapping region between those sunken region 15 of the oxide layer 14 and the second oxide layer 16 is formed a first window-type isolating channel 17. The overlapping region between of the first window-type isolating channel 17 of the second oxide layer 16 and the polysilicon layer 18 is formed a second window-type isolating channel 19. The thickness of the overlapping region between the first window-type isolating channel 17 and the second window-type isolating channel 19 is thinner than other regions behind the overlapping region.

In other words, the present invention uses the action of the first window-type isolating channel 17 and the second window-type isolating channel 19 to set a thin window-type isolating channel on the P type semiconductor-implanted region of the N type semiconductor substrate so as to the post-process programming process of the present structure can be performed by applying a voltage thereon to penetrate those window-type isolating channels 17, 19 to form a P-N junction between the polysilicon layer and the P type semiconductor-implanted regions 12. It should be recognized that the N type semiconductor substrate 10 might be replaced with the N-well region of the P type semiconductor substrate.

Certainly, the mentioned embodiment of the present invention uses an N type semiconductor as a substrate and it should be recognized that it might be replaced with a P type semiconductor as a substrate or an N-well region of the P type semiconductor as a substrate. Moreover, those sunken regions 15 of the first oxide layer 14 can be formed by prior technology, such as the lithographic process. Furthermore, those sunken regions 15 of the first oxide layer 14 can be formed not only to completely expose the substrate 10 but also can be formed by partially removed without exposing the substrate. On the other way, due to the cross-section width of the second window-type isolating channel 19 is smaller than or equal to the cross-section width of the P+type semiconductor-implanted regions 12 and positioned aligned within the cross-section width of the P+type semiconductor-implanted regions 12, so in the post-process programming process, the voltage can precisely applied thereon to penetrate the second oxide layer 16 to effectively form a junction there between so as to enhance the stability of the programming process.

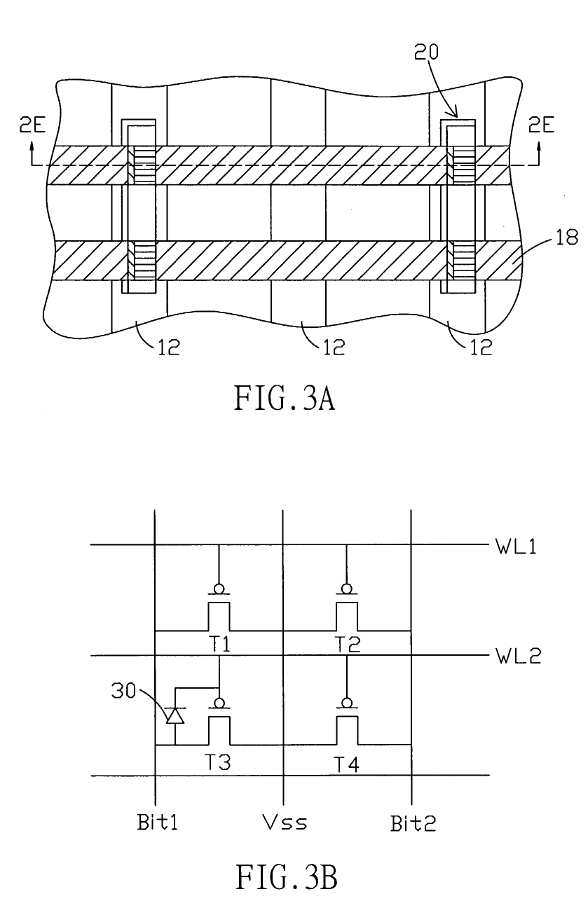

Referring to the FIG. 3A and FIG. 3B, there are an array structure and its array circuit of the preferred embodiment of the present invention. As shown in figures, by using the lithographic technology, the polysilicon layer 18 is etched as bar-positioned or other spaced appropriately on the second oxide layer 16, which is used as the gate electrode of the ROM cell. The gate electrode is the word line of the array control wire and the P+type semiconductor-implanted region 12 is the bit line of the array control wire. Moreover, an integrated window-type isolating channel 20 is formed by combining a portion of the first window-type isolating channel 17 and a portion of the second window-type isolating channel 19, as shown in the FIG. 3A.

In the programming process, such as of the T3 ROM cell, a voltage Vₚₚ is applied to the word line WL2 and a voltage V_{CC} is applied to the word line WL1. When the bit line Bit1 is set at zero voltage and the bit line Bit2 is at V_{CC} voltage, the T3 ROM cell is programmed accordingly by providing a P-N diode 30 in the T3 ROM cell, as shown in the FIG. 3B. In the reading process, it only needs a voltage V_{CC} applied to the bit line Bit1 and the word line WL2 if it requires to turn on the T1 ROM cell. Furthermore, it only needs a voltage V_{CC} applied to the bit line Bit1 and the word line WL1 and a zero voltage applied to the bit line Bit2 and the word line WL2 if it requires turning off the T3 ROM cell.

Owing to without the require of simultaneously performing the programming process in the manufacture process, the manufacturers can instantaneously perform the programming process of the post-process OTP ROM cell, which are available goods, after receiving the order from customers. The present invention can enhance the maneuverability of the supply but without the pressure from storing the large number of stocks.

Of course, it is to be understood that the invention described herein need not be limited to these disclosed embodiments. Various modification and similar changes are still possible within the spirit of this invention. In this way, all such variations and modifications are included within the intended scope of the invention and the scope of this invention should be defined by the appended claims.

What is claimed is:

1. A structure of a post-process one-time programmable (OTP) read only memory cell (ROM cell), said structure comprising:
a semiconductor substrate having a plurality of semiconductor-implanted regions respectively to divide into a drain region and a source region;
a first dielectric on a surface of said semiconductor substrate;
a second dielectric on a surface of said second dielectric; and
a polysilicon layer on a surface of said second dielectric, wherein said polysilicon layer is used as a gate electrode region.

2. The structure of said ROM cell according to claim 1, wherein said first dielectric has a plurality of sunken portions and each of said sunken portions is respective to a plurality of P+type semiconductor-implanted regions of said N type semiconductor substrate.

3. The structure of said ROM cell according to claim 2, wherein an overlapping region of said sunken portions of said first dielectric and said second dielectric is formed a first window-type isolating channel.

4. The structure of said ROM cell according to claim 3, wherein an overlapping portion of said first window-type isolating channel of said second dielectric and said polysilicon layer is formed a second window-type isolating channel.

5. The structure of said ROM cell according to claim 4, wherein a thickness of an overlapping region of said first window-type isolating channel and said second window-type isolating channel is smaller than other portion beyond said overlapping portion.

6. The structure of said ROM cell according to claim 1, wherein said dielectric can be made of an oxide layer.
